(19) United States
(12) Patent Application Publication
(10) Pub. No.: US 2024/0079661 A1
(43) Pub. Date: Mar. 7, 2024

(54) ADAPTIVE TUNING CIRCUIT FOR WIRELESS SIGNAL TRANSMISSION

(71) Applicant: GM GLOBAL TECHNOLOGY OPERATIONS LLC, Detroit, MI (US)

(72) Inventor: Aseim M. Elfrgani, Sterling Heights, MI (US)

(73) Assignee: GM GLOBAL TECHNOLOGY OPERATIONS LLC, Detroit, MI (US)

(21) Appl. No.: 17/901,039

(22) Filed: Sep. 1, 2022

(51) Int. Cl. H01M 10/42; G01K 13/00; G01R 31/3835; G01R 31/396; H01M 10/48; H02J 7/00

(52) U.S. Cl. CPC H01M 10/425; G01K 13/00; G01R 31/3835; G01R 31/396; H01M 10/486; H02J 7/00032; H02J 7/0013; H02J 7/0047; H04B 1/04

(57) ABSTRACT

A battery cell monitoring system includes a battery cell monitoring unit, including a controller, a battery monitoring sensor, and a radiofrequency (RF) signal manager electrically connected to a first RF antenna via a transmission link, wherein the transmission link includes an adaptive tuning circuit; and a battery management system in communication with a second RF antenna. The battery monitoring sensor is arranged to monitor a parameter of a battery cell, the RF signal manager generates a signal having a parametric component and a control component, wherein the control component dynamically controls the adaptive tuning circuit, and the RF signal manager wirelessly communicates the signal between the battery cell monitoring unit and the battery management system via the first RF antenna and the second RF antenna.

### INTRODUCTION

Electrochemical battery cells may be arranged in cell modules that are interconnected and secured within a housing. There may be multiple cell modules arranged in a high-voltage battery pack, which are interconnected to provide electrical power to a system such as an electrified powertrain system.

A cell monitoring unit (CMU) may be joined to an individual cell module to monitor the battery cells, including monitoring cell voltages, currents, temperatures, and other parameters. The CMU may be equipped with a wireless communication circuit that communicates with a battery system manager (BSM), wherein the BSM is responsible to monitor inputs from the CMU and execute control routines related to charging, discharging, etc., in response.

Information from one or multiple CMUs may be wirelessly communicated to a battery controller for storage, monitoring, and further analysis.

Transmission of wireless communications may be subject to power loss in transmission lines to antennas and during wireless transmission. To reduce transmission line losses, an antenna needs to be tuned to or matched to a respective transmission line. Known systems for reducing transmission line losses employ reactive, passive elements such as capacitors and inductors, and require individual tuning in a representative environment, which can be subject to change.

### SUMMARY

There is a need for a short-range wireless communication circuit that adapts wireless communication based upon at least one of a location, structure, or environment of a sending unit in relation to a receiving unit.

The concepts described herein provide a system, apparatus, and/or method for controlling and managing wireless communication between a sending unit and a receiving unit, such as a battery system manager (BMS) and a cell monitoring unit (CMU) that can adapt wireless communication based upon at least one of a location, structure, or environment of a sending unit in relation to a receiving unit.

An aspect of the disclosure includes a battery cell monitoring system including a battery cell monitoring unit, including a controller, a battery monitoring sensor, and a radiofrequency (RF) signal manager electrically connected to a first RF antenna via a transmission link, wherein the transmission link includes an adaptive tuning circuit; and a battery management system in communication with a second RF antenna. The battery monitoring sensor is arranged to monitor a parameter of a battery cell, the RF signal manager generates a signal having a parametric component and a control component, wherein the control component dynamically controls the adaptive tuning circuit, and the RF signal manager wirelessly communicates the signal between the battery cell monitoring unit and the battery management system via the first RF antenna and the second RF antenna.

Another aspect of the disclosure may include the adaptive tuning circuit being a varactor diode.

Another aspect of the disclosure may include the varactor diode being arranged in series between the RF signal manager and the RF antenna.

Another aspect of the disclosure may include the varactor diode being arranged between the RF signal manager and the RF antenna, wherein the varactor diode is electrically connected to ground.

Another aspect of the disclosure may include the adaptive tuning circuit and conductive lead composed as a meander line arranged between the RF signal manager and the first RF antenna.

Another aspect of the disclosure may include the control component of the signal being generated by the RF signal manager controls the varactor diode of the adaptive tuning circuit.

Another aspect of the disclosure may include the signal generated by the RF signal manager is based upon the control component of the signal generated by the RF signal manager.

Another aspect of the disclosure may include the adaptive tuning circuit being a plurality of varactor diodes, wherein the plurality of varactor diodes includes a first varactor diode arranged in series between the RF signal manager and the RF antenna, a second varactor diode coupled to a first node arranged between the first varactor diode and the RF signal manager, wherein the second varactor diode is electrically connected to ground, and a third varactor diode coupled to a second node arranged between the first varactor diode and the RF antenna, wherein the third varactor diode is electrically connected to ground.

Another aspect of the disclosure may include the control component of the signal generated by the RF signal manager controlling the plurality of varactor diodes of the adaptive tuning circuit.

Another aspect of the disclosure may include the signal generated by the RF signal manager being based upon the control component of the signal generated by the RF signal manager.

Another aspect of the disclosure may include the battery monitoring sensor being a temperature sensor arranged to monitor a temperature of the battery cell; and wherein the parametric component of the signal includes the temperature of the battery cell.

Another aspect of the disclosure may include the battery monitoring sensor being a voltage sensor arranged to monitor a voltage of the battery cell; and wherein the parametric component of the signal includes the voltage of the battery cell.

Another aspect of the disclosure may include the control component dynamically controlling the adaptive tuning circuit to match the first RF antenna of the battery cell monitoring unit to the second RF antenna of the battery management system.

Another aspect of the disclosure may include the control component dynamically controlling the adaptive tuning circuit to match the first RF antenna of the battery cell monitoring unit to the second RF antenna of the battery management system based upon at least one of a location, structure, or environment of the first RF antenna of the battery cell monitoring unit in relation to the second RF antenna of the battery management system.

Another aspect of the disclosure may include the battery cell monitoring system including a plurality of battery cell monitoring units arranged to monitor a plurality of battery cells; and a battery management system, wherein each battery cell monitoring unit is arranged to monitor a respective one of the plurality of battery cells, and includes a respective controller, a respective battery monitoring sensor, and a respective radiofrequency (RF) signal manager electrically connected to a respective first RF antenna via a respective transmission link, and wherein the respective transmission link includes a respective adaptive tuning circuit; and wherein the battery management system is in communication with a second RF antenna. The respective battery monitoring sensor is arranged to monitor a parameter of the respective one of the plurality of battery cells, the respective RF signal manager generates a respective signal having a parametric component and a control component, the control component dynamically controls the respective adaptive tuning circuit, and the respective RF signal manager wirelessly communicates the respective signal between the respective battery cell monitoring unit and the battery management system via the respective first RF antenna and the second RF antenna.

Another aspect of the disclosure may include a short-range communication circuit, including a radiofrequency (RF) signal manager electrically connected to an RF antenna via a transmission link, wherein the transmission link includes an adaptive tuning circuit including a plurality of varactor diodes, wherein the RF signal manager generates a signal that is communicated to the RF antenna for wireless transmission; and wherein the signal generated by the RF signal manager includes a control component for dynamically controlling the plurality of varactor diodes of the adaptive tuning circuit.

Another aspect of the disclosure may include a short-range communication circuit that includes a radiofrequency (RF) signal manager electrically connected to an RF antenna via a transmission link, wherein the transmission link includes an adaptive tuning circuit; wherein the RF signal manager generates a signal that is communicated to the RF antenna for wireless transmission; and wherein the signal generated by the RF signal manager includes a control component for dynamically controlling the adaptive tuning circuit.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

One or more embodiments will now be described, by way of example, with reference to the accompanying drawings, in which:

FIG. 1 is an exploded view illustration of a representative rechargeable electrical energy storage system, in accordance with the present disclosure.

FIG. 2 is a schematic plan view illustration of the representative rechargeable electrical energy storage system of FIG. 1, in accordance with the disclosure.

FIG. 3 is a schematic illustration of a vehicle powertrain system that may employ the representative rechargeable electrical energy storage system of FIG. 1.

FIG. 4 is a schematic illustration of an adaptive tuning circuit, in accordance with the disclosure.

FIG. 5 is a schematic illustration of a representative control signal, in accordance with the disclosure.

The appended drawings are not necessarily to scale, and may present a simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments may be practiced without some of these details. Moreover, for the purpose of clarity, certain technical material that is understood in the related art has not been described in detail to avoid unnecessarily obscuring the disclosure. Furthermore, the disclosure, as illustrated and described herein, may be practiced in the absence of an element that is not specifically disclosed herein.

As used herein, the term “system” may refer to one of or a combination of mechanical and electrical actuators, sensors, controllers, application-specific integrated circuits (ASIC), combinatorial logic circuits, software, firmware, and/or other components that are arranged to provide the described functionality.

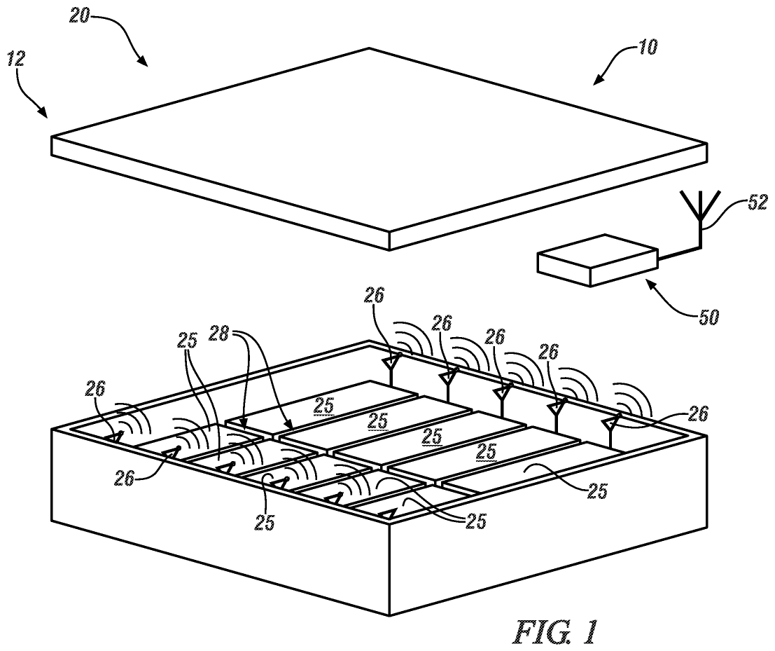

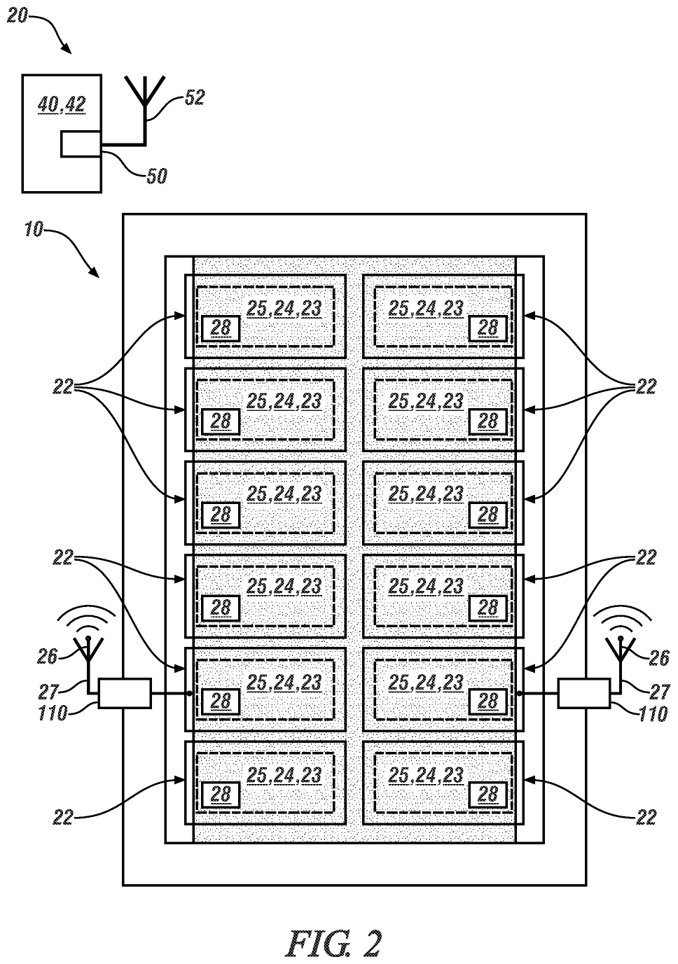

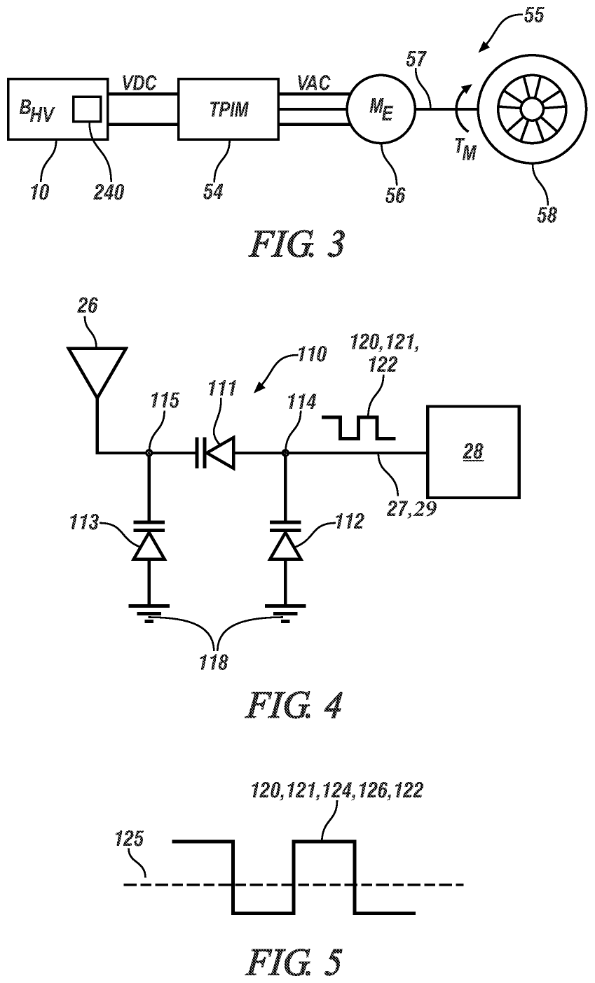

Referring to the drawings, wherein like reference numbers refer to like features throughout the several views, FIGS. 1 and 2 depict elements of a battery cell monitoring system 20 that is configured to wirelessly monitor elements of a rechargeable electrical energy storage system (RESS) 10. In one embodiment, and as described with reference to FIG. 3, the RESS 10 and battery cell monitoring system 20 are arranged to supply electric power to one or multiple electric machines to provide tractive effort in a vehicle having an electrified powertrain. The vehicle may include, but is not limited to a mobile platform in the form of a commercial vehicle, industrial vehicle, agricultural vehicle, passenger vehicle, aircraft, watercraft, train, all-terrain vehicle, personal movement apparatus, robot, and the like to accomplish the purposes of this disclosure.

Referring again to FIGS. 1 and 2, the RESS 10 is composed of a plurality of interconnected battery cell module assemblies (BCMA) 22 that are contained within an enclosure 12 and a battery management system (BMS) 40 that includes a BMS controller 42. Each of the BCMAs 22 is composed of a plurality of rechargeable electrochemical battery cells (battery cells) 24 and an associated cell monitoring unit (CMU) 25. The battery cells 24 are lithium ion battery cells in one embodiment, although the disclosure is not so limited.

The RESS 10 includes a battery pack that includes multiple battery cell module assemblies (BCMA) 22 and a radio frequency manager 28 configured to communicate wirelessly with the BMS controller 42. The BCMAs 22 may be arranged side-by-side, in rows, etc., in the enclosure 12, or in separate enclosures. For example, there may be sixteen, twenty-eight, or another number of BCMAs 22 in the enclosure 12. Furthermore, in some implementations, the RESS 10 may include multiple battery packs. In most such wireless communications, the BCMA 22 is transmitting the radio frequency signal (e.g., acting as a transmitter) while the BMS controller 42 is receiving the signal (e.g., acting as a receiver), but in some instances the RF signal manager 28 sends the wireless signal to the BCMA 22 (e.g., acts as a transmitter while the BCMA 22 acts as a receiver).

Each of the CMUs 25 includes one or multiple cell monitoring sensors 23, a radio frequency signal manager 28, a first radiofrequency (RF) antenna 26, and a transmission link 27 including an adaptive tuning circuit 110 and one or multiple conductive leads 29.

The cell monitoring sensors 23 are arranged to monitor parameters of the respective battery cells, and include one or more of a temperature sensor, a voltage sensor, a current sensor, etc. The cell monitoring sensors 23 may be arranged to monitor individual battery cells, or individual BCMAs 22.

The radio frequency signal manager 28 is electrically coupled to the first radiofrequency (RF) antenna 26 via the transmission link 27, wherein the transmission link 27 includes the adaptive tuning circuit 110 and the conductive lead 29. Embodiments of the adaptive tuning circuit 110 are described and illustrated with reference to FIG. 4.

The BMS controller 42 of the BMS 40 communicates via a radiofrequency (RF) receiver 50 having a second RF antenna 52. The RF receiver 50 is capable of monitoring signal strength of the RF signal from the first RF antenna 26. The BMS controller 42 communicates the signal strength of the RF signal from the first RF antenna 26 to the respective radio frequency signal manager 28 of the respective BCMA 22, which is able to adjust a control component 122 of a signal 120 generated by the RF signal manager of the CMU 25 to tune the respective first RF antenna 26 to minimize signal transmission losses.

In operation the first RF antenna 26 may primarily operate as a transmitting (Tx) antenna, and the second RF antenna 52 may primarily operate as a receiving (Rx) antenna. However, communication between the CMUs 25 and the BMS 40 may be two-way communication, with the first RF antenna 26 operating as both a transmitting (Tx) antenna and a receiving (Rx) antenna, and the second RF antenna 52 operating as both a transmitting (Tx) antenna and a receiving (Rx) antenna.

Wireless communication occurs over wireless communications pathways within the enclosure using communications protocols, e.g., a Wi-Fi protocol using a wireless local area network (WLAN), IEEE 802.11, a 3G, 4G, or 5G cellular network-based protocol, BLUETOOTH™, BLE BLUETOOTH, and/or other protocol. Additional or alternate communication methods, such as a dedicated short-range communications (DSRC) channel, near field communication (NFC), etc., are also considered within the scope of the present disclosure. As appreciated in the art, DSRC channels refer to one-way or two-way short-range to medium-range wireless communication channels specifically designed for automotive use and a corresponding set of protocols and standards.

The presence of multiple RF transmitting nodes 26, along with the various other structural elements of the RESS 10, may result in degraded RF signal fidelity due to, e.g., signal interference, close proximity of competing RF transmitting nodes 26, and other factors as noted above.

An RF receiver (Rx) 50 including receiving antenna 52 may be positioned within the enclosure in wireless communication with the RF transmitting nodes 26, with the particular location of the RF receiver 50 possibly varying with the given application.

Referring to FIG. 2, each respective one of the CMUs 25 may be a component of one of the BCMAs 22. In any or all of such possible constructions, the CMUs 25 described herein may be mounted either on top of or on the side of the BCMAs 22.

Each respective one of the CMUs 25 includes, as the respective RF transmitting node 26 of FIG. 1, an RF antenna 26 in communication with the RF receiver 50 of FIG. 1. For simplicity, FIG. 2 illustrates two of the RF antennas 26, with each of the remaining RF transmitting nodes 26 being similarly equipped with a corresponding RF antenna 26. The RF receiver 50 in this embodiment includes RF antenna 52 of an electronic control unit 240 for the RESS 10, sometimes referred to as battery management system (BMS).

FIG. 3 is a schematic diagram of a vehicle powertrain 55 including a rechargeable energy storage system (RESS) 10. The vehicle powertrain 55 may be for an electrified vehicle, e.g., a powertrain including solely electrical power sources for motive power, such as electric motor/generators, or a hybrid electric vehicle having a powertrain including both an electrical power source used for propulsion, and another power source for propulsion, such as an internal combustion engine or a fuel cell, for example. The RESS 10 provides electrical energy (VDC) to one or more power sources, such as a motor-generator 56, via a power inverter 54. The motor-generator 56 provides motive torque (T_{M}) 57 to a load 58, such as a vehicle drivetrain. Controller 240 receives data indicative of operating parameters of the BCMAs 22, such as cell voltages and charging and discharging currents, via signals from the RF signal manager 28 and may be physically connected thereto (e.g., wired to the RF signal manager 28). Although shown as a single controller 240, there may be multiple controllers interconnected as a control system. The same or a different controller 240 may also receive other vehicle information, such as acceleration and braking demands, and may command operation of the motor-generator 56 by sending control signals to the motor controller.

FIG. 4 schematically illustrates an embodiment of the adaptive tuning circuit 110, which is arranged in the transmission link 27 between the RF signal manager 28 and the first RF antenna 26 of a respective one of the CMUs 25. In one embodiment, the adaptive tuning circuit 110 is composed of a plurality of varactor diodes, including a first varactor diode 111, a second varactor diode 112, and a third varactor diode 113. The first varactor diode 111 is arranged in series between the RF signal manager 28 and the RF antenna 26, with a cathode oriented towards the RF antenna 26 and an anode oriented towards the RF signal manager 28. The second varactor diode 112 includes a cathode that is coupled to a first node 114 that is arranged between the first varactor diode 111 and the RF signal manager 28, and an anode that is electrically connected to ground 118. The third varactor diode 113 includes a cathode that is coupled to a second node 115 that is arranged between the first varactor diode 111 and the RF antenna 26, and an anode electrically connected to ground 118.

The RF signal manager 28 generates a signal 120 for wireless transmission via the RF antenna 26. The signal 120 has a parametric component 121 and a control component 122. The parametric component 121 of the signal 120 contains one or multiple parameters from the cell monitoring sensors 23 arranged to monitor parameters of the respective battery cell 24 or module 20, including, e.g., voltage, temperature, current, etc.

The control component 122 of the signal 120 generated by the RF signal manager 28 contains information for controlling the plurality of varactor diodes of the adaptive tuning circuit 110. In one embodiment, the signal generated by the RF signal manager 28 includes a pulsewidth-modulated (PWM) signal having a frequency and a duty cycle, wherein the duty cycle of the PWM signal is based upon the control component 122 of the signal 120 generated by the RF signal manager 28 of the CMU 25. In operation, the BMS controller 42 communicates the signal strength of the RF signal that is received from the respective first RF antenna 26 to the respective radio frequency signal manager 28 of the respective BCMA 22. The BMS controller 42 communicates the signal strength of the RF signal from the first RF antenna 26 to the respective radio frequency signal manager 28 of the respective BCMA 22, which is able to adjust the control component 122 of the signal 120 generated by the RF signal manager 28 of the CMU 25 to tune the respective first RF antenna 26 to minimize signal transmission losses.

A varactor diode is a simple variable capacitor that allows oscillator circuits and other circuits to be easily tuned by applying a voltage. These diodes have a similar structure as a p-n diode; the structure of a varactor diode is rather simple and illustrates its power as a component with nonlinear reactance. These diodes have a p-n-n+structure, where the applied voltage modulates the width of the depletion region between the p and n+sides. When run with an AC small signal that has a DC offset, it may function as a linear component with minimal signal distortion. A varactor diode is run in reverse bias, where an applied voltage changes the width of the depletion region. When the reverse bias voltage is increased, the width of the depletion region also increases, which decreases the capacitance. In one embodiment, tuning of an RF circuit includes inputting an input AC signal with DC offset (Vdc). In one embodiment, the DC offset may be achieved employing pulsewidth-modulation techniques. Specifications include the capacitance value and capacitance-voltage change behavior. The reverse breakdown characteristic may also be important because quite high reverse voltages may be needed to reduce the capacitance of the diode to the bottom values. Another parameter of importance is the quality factor or Q of the diode as this can have a significant impact on the performance of the overall circuit. Low levels of Q can reduce the selectivity of a filter, or adversely affect the phase noise of an oscillator using a varactor.

Alternatively, the adaptive tuning circuit 110 is composed of a single varactor diode, e.g., the first varactor diode 111 arranged in series between the RF signal manager 28 and the RF antenna 26, with its cathode oriented towards the RF antenna 26 and its anode oriented towards the RF signal manager 28.

Alternatively, the adaptive tuning circuit 110 is composed of a single varactor diode, e.g., the third varactor diode 113 with its cathode coupled to the second node 115 that is arranged between the RF signal manager 28 and the RF antenna 26, and its anode electrically connected to ground 118.

Alternatively, the adaptive tuning circuit 110 is composed of two varactor diodes, including the first varactor diode 111 arranged in series between the RF signal manager 28 and the RF antenna 26, with its cathode oriented towards the RF antenna 26 and its anode oriented towards the RF signal manager 28, and the second varactor diode 112 with its cathode coupled to the first node 114 that is arranged between the first varactor diode 111 and the RF signal manager 28, and its anode electrically connected to ground 118.

Alternatively, the adaptive tuning circuit 110 is composed of two varactor diodes, including the first varactor diode 111 arranged in series between the RF signal manager 28 and the RF antenna 26, with its cathode oriented towards the RF antenna 26 and its anode oriented towards the RF signal manager 28, and the third varactor diode 113 with its cathode coupled to the second node 115 that is arranged between the first varactor diode 111 and the RF antenna 26, and its anode electrically connected to ground 118.

In one embodiment, the inductive impedance of the RF antenna 26 may be adjusted to reduce the quantity of the varactor diodes. Adjusting the inductive impedance of the RF antenna 26 may be accomplished through design of the RF antenna 26 and design of the transmission link 27. The design of the transmission link 27 may include the length of the conductive lead 29 of the transmission link 27 in front of the RF antenna 26, which may be selected in combination with the design of the adaptive tuning circuit 110 to achieve the desired inductive impedance in one embodiment. This may include designing the conductive lead 29 of the transmission link 27 to incorporate a meander line between the RF signal manager 28 and the adaptive tuning circuit 110 to adjust the length and thus adjust the inductive behavior of the RF antenna 26 to achieve the desired inductive impedance in combination with the first and third varactor diodes 111, 113. Alternatively, or in combination, this may include designing the conductive lead 29 of the transmission link 27 to incorporate a meander line between the adaptive tuning circuit 110 and the RF antenna 26 to adjust the length and thus adjust the inductive behavior of the RF antenna 26 to achieve the desired inductive impedance in combination with the first and third varactor diodes 111, 113.

FIG. 5 graphically depicts an embodiment of a portion of the control signal 120 described herein. The control signal 120 may be characterized as having a parametric component 121, a control component 122 in the form of peak-to-peak magnitude, frequency 124, and a DC offset 126 from a zero line 125.

The RF signal manager 28 described herein can advantageously manage and control one or more of the parametric component 121, the control component 122 in the form of peak-to-peak magnitude, frequency 124, and the DC offset 126 from the zero line 125 to dynamically control the adaptive tuning signal 110 to match the first RF antenna of the battery cell monitoring unit to the second RF antenna of the battery management system based upon at least one of a location, structure, or environment of the first RF antenna of the battery cell monitoring unit in relation to the second RF antenna of the battery management system.

Automatic tuning of the adaptive tuning signal 110 for one of the CMUs 25 may be accomplished by sensing the reflected signal at the RF chip input and adjusting or tuning the control signal to the adaptive tuning signal 110 to tune or match the first RF antenna of the respective CMU with the second RF antenna of the BMS to achieve optimal RF performance.

The use of the adaptive tuning signal 110 to automatically match or tune a network for cell monitoring unit and the battery signal manager antennas improves the RF wireless signal strength by reducing the losses in the feeding network due to mismatch, which may occur when using the CMUs and BRFM at different locations, structures, configurations, and environments.

This serves to maintain the optimal RF wireless performance for all the CMUs and BRFM antennas (so that BMS) at different locations in a battery pack, at different module configurations, at different battery packs configurations, and also different surrounding environments.

This improves the RF wireless signal when CMUs and BRFM are integrated tightly to different complex structures and environments, such as using the same CMU at different cell module assembly (CMA) configurations, having different surroundings, different environments, e.g., high humidity/waterized pack, immersed pack using three varactors to optimally tune/match the CMUs and BRFM antenna automatically.

Embodiments may be described herein in terms of functional and/or logical block components and various processing steps. It should be appreciated that such block components may be realized by any number, combination or collection of mechanical and electrical hardware, software, and/or firmware components configured to perform the specified functions. For example, an embodiment may employ various combinations of mechanical components and electrical components, integrated circuit components, memory elements, digital signal processing elements, logic elements, look-up tables, or the like, which may carry out a variety of functions under the control of one or more microprocessors or other control devices. Embodiments may be practiced in conjunction with any number of mechanical and/or electronic systems, and that the vehicle systems described herein are merely examples of possible implementations.

The term “controller” and related terms such as control module, module, control, control unit, processor and similar terms refer to one or various combinations of Application Specific Integrated Circuit(s) (ASIC), Field-Programmable Gate Array (FPGA), electronic circuit(s), central processing unit(s), e.g., microprocessor(s) and associated non-transitory memory component(s) in the form of memory and storage devices (read only, programmable read only, random access, hard drive, etc.). The non-transitory memory component is capable of storing machine readable instructions in the form of one or more software or firmware programs or routines, combinational logic circuit(s), input/output circuit(s) and devices, signal conditioning and buffer circuitry and other components that can be accessed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms and similar terms mean controller-executable instruction sets including calibrations and look-up tables. Each controller executes control routine(s) to provide desired functions. Routines may be executed at regular intervals, for example each 100 microseconds during ongoing operation. Alternatively, routines may be executed in response to occurrence of a triggering event. Communication between controllers, and communication between controllers, actuators and/or sensors may be accomplished using a direct wired point-to-point link, a networked communication bus link, a wireless link or another suitable communication link. Communication includes exchanging data signals in suitable form, including, for example, electrical signals via a conductive medium, electromagnetic signals via air, optical signals via optical waveguides, and the like. The data signals may include discrete, analog or digitized analog signals representing inputs from sensors, actuator commands, and communication between controllers.

The term “signal” refers to a physically discernible indicator that conveys information, and may be a suitable waveform (e.g., electrical, optical, magnetic, mechanical or electromagnetic), such as DC, AC, sinusoidal-wave, triangular-wave, square-wave, vibration, and the like, that is capable of traveling through a medium.

A parameter is defined as a measurable quantity that represents a physical property of a device or other element that is discernible using one or more sensors and/or a physical model. A parameter may be a discrete value (e.g., either “1” or “0”), a percentage (e.g., 0% to 100%), or an infinitely variable value.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

1. A battery cell monitoring system, comprising:
a battery cell monitoring unit, including a controller, a battery monitoring sensor, and a radiofrequency (RF) signal manager electrically connected to a first RF antenna via a transmission link, wherein the transmission link includes an adaptive tuning circuit; and
a battery management system in communication with a second RF antenna;
wherein the battery monitoring sensor is arranged to monitor a parameter of a battery cell;
wherein the RF signal manager generates a signal having a parametric component and a control component;
wherein the control component dynamically controls the adaptive tuning circuit; and
wherein the RF signal manager wirelessly communicates the signal between the battery cell monitoring unit and the battery management system via the first RF antenna and the second RF antenna.

2. The battery cell monitoring system of claim 1, wherein the adaptive tuning circuit comprises a varactor diode.

3. The battery cell monitoring system of claim 2, wherein the varactor diode is arranged in series between the RF signal manager and the first RF antenna.

4. The battery cell monitoring system of claim 2, wherein the varactor diode is arranged between the RF signal manager and the first RF antenna, wherein the varactor diode is electrically connected to ground.

5. The battery cell monitoring system of claim 2, wherein the control component of the signal generated by the RF signal manager controls the varactor diode of the adaptive tuning circuit.

6. The battery cell monitoring system of claim 2, wherein the signal generated by the RF signal manager is based upon the control component of the signal generated by the RF signal manager.

7. The battery cell monitoring system of claim 1, wherein the adaptive tuning circuit comprises a plurality of varactor diodes, wherein the plurality of varactor diodes includes:
a first varactor diode arranged in series between the RF signal manager and the first RF antenna, a second varactor diode coupled to a first node arranged between the first varactor diode and the RF signal manager, wherein the second varactor diode is electrically connected to ground, and a third varactor diode coupled to a second node arranged between the first varactor diode and the first RF antenna, wherein the third varactor diode is electrically connected to ground.

8. The battery cell monitoring system of claim 7, wherein the control component of the signal generated by the RF signal manager controls the plurality of varactor diodes of the adaptive tuning circuit.

9. The battery cell monitoring system of claim 7, wherein the signal generated by the RF signal manager is based upon the control component of the signal generated by the RF signal manager.

10. The battery cell monitoring system of claim 1, wherein the battery monitoring sensor comprises a temperature sensor arranged to monitor a temperature of the battery cell; and wherein the parametric component of the signal includes the temperature of the battery cell.

11. The battery cell monitoring system of claim 1, wherein the battery monitoring sensor comprises a voltage sensor arranged to monitor a voltage of the battery cell; and wherein the parametric component of the signal includes the voltage of the battery cell.

12. The battery cell monitoring system of claim 1, wherein the control component dynamically controls the adaptive tuning circuit to match the first RF antenna of the battery cell monitoring unit to the second RF antenna of the battery management system.

13. The battery cell monitoring system of claim 12, wherein the control component dynamically controls the adaptive tuning circuit to match the first RF antenna of the battery cell monitoring unit to the second RF antenna of the battery management system based upon at least one of a location, structure, or environment of the first RF antenna of the battery cell monitoring unit in relation to the second RF antenna of the battery management system.

14. The battery cell monitoring system of claim 1, wherein the transmission link includes the adaptive tuning circuit and conductive lead composed as a meander line arranged between the RF signal manager and the first RF antenna.

15. A battery cell monitoring system, comprising:
a plurality of battery cell monitoring units arranged to monitor a plurality of battery cells; and
a battery management system;
wherein each battery cell monitoring unit is arranged to monitor a respective one of the plurality of battery cells, and includes a respective controller, a respective battery monitoring sensor, and a respective radiofrequency (RF) signal manager electrically connected to a respective first RF antenna via a respective transmission link, and wherein the respective transmission link includes a respective adaptive tuning circuit; and
wherein the battery management system is in communication with a second RF antenna;
wherein the respective battery monitoring sensor is arranged to monitor a parameter of the respective one of the plurality of battery cells;
wherein the respective RF signal manager generates a respective signal having a parametric component and a control component;
wherein the control component dynamically controls the respective adaptive tuning circuit; and
wherein the respective RF signal manager wirelessly communicates the respective signal between the respective battery cell monitoring unit and the battery management system via the respective first RF antenna and the second RF antenna.

16. The battery cell monitoring system of claim 15, wherein the respective adaptive tuning circuit comprises a varactor diode.

17. The battery cell monitoring system of claim 16, wherein the control component of the respective signal generated by the respective RF signal manager controls the varactor diode of the adaptive tuning circuit.

18. The battery cell monitoring system of claim 15, wherein the respective control component dynamically controls the respective adaptive tuning circuit to match the respective first RF antenna of the battery cell monitoring unit to the second RF antenna of the battery management system based upon at least one of a location, structure, or environment of the respective first RF antenna of the respective battery cell monitoring unit in relation to the second RF antenna of the battery management system.

19. A short-range communication circuit, comprising:
a radiofrequency (RF) signal manager electrically connected to a first RF antenna via a transmission link;
wherein the transmission link includes an adaptive tuning circuit including a plurality of varactor diodes;
wherein the RF signal manager generates a signal that is communicated to the first RF antenna for wireless transmission; and
wherein the signal generated by the RF signal manager includes a control component for dynamically controlling the plurality of varactor diodes of the adaptive tuning circuit.

20. The short-range communication circuit of claim 19, wherein the control component dynamically controls the adaptive tuning circuit to match the first RF antenna to a second RF antenna based upon at least one of a location, structure, or environment of the first RF antenna in relation to the second RF antenna.
